(19) United States
(12) Patent Application Publication
(10) Pub. No.: US 2026/0059741 A1
(43) Pub. Date: Feb. 26, 2026

(54) SEMICONDUCTOR DEVICE

(71) Applicant: Fujian Jinhua Integrated Circuit Co., Ltd., Quanzhou City (CN)

(72) Inventors: Li-Wei Feng, Quanzhou City (CN); Janbo Zhang, Quanzhou City (CN); Yirong Xu, Quanzhou City (CN)

(73) Assignee: Fujian Jinhua Integrated Circuit Co., Ltd., Quanzhou City (CN)

(21) Appl. No.: 19/034,523

(22) Filed: Jan. 22, 2025

(30) Foreign Application Priority Data
Aug. 20, 2024 (CN) 202411147311.0

(51) Int. Cl. H10B 12/00; H01L 21/762

(52) U.S. Cl. CPC H10B 12/482; H01L 21/76224

(57) ABSTRACT

The present disclosure includes a semiconductor device and a method of fabricating the same, with the semiconductor device including a substrate, a shallow trench isolation and a plurality of bit line structures. The substrate includes a plurality of active areas. The shallow trench isolation is disposed in the substrate and includes a first insulating layer and a second insulating layer. The bit line structures are disposed on the substrate. At least one of the bit line structures intersects the active areas, the first insulating layer and the second insulating layer, and respectively includes a first insulating stacked structure, a second insulating stacked structure and a third insulating stacked structure over the active areas, the first insulating layer and the second insulating layer, with each insulating stacked structure include a top surface being coplanar with each other and different stacked materials from each other.

### BACKGROUND OF THE INVENTION

### 1. Field of the Invention

The present disclosure generally relates to a semiconductor device, and more particularly, to a semiconductor device with a bit line structure.

### 2. Description of the Prior Art

With the trend of miniaturization of various electronic products, the design of semiconductor memory devices must meet the requirements of high integration and high density. For a dynamic random access memory (DRAM) having recessed gate structures, because the carrier channel of which is relatively long in the same semiconductor substrate compared with that of the DRAM without recessed gate structures, the leakage current from the capacitor structure in the DRAM can be reduced. Therefore, the DRAM having recessed gate structures has gradually replaced DRAM having planar gate structures under the current mainstream development trend. Generally, the DRAM having recessed gate structure is constructed by a large number of memory cells which are arranged to form an array area, and each of the memory cells can be used to store information. Each memory cell may include a transistor element and a capacitor element connected in series, which is configured to receive voltage information from word lines (WL) and bit lines (BL). In order to fulfill the requirements of advanced products, the density of memory cells in the array area must be further increased, which increases the difficulty and complexity of related fabricating processes and designs. Therefore, the present technology needs further improvement to effectively improve the efficiency and reliability of related memory devices.

### SUMMARY OF THE INVENTION

One of the objectives of the present disclosure provides a semiconductor device, where a plurality of insulating stacked structures each having a coplanar top surface and different stacked materials is disposed on a conductive layer of a bit line structure, such that, the bit line structure enables to achieve various insulating performances in different extending regions corresponding thereto, thereby improving the function and the operation of the semiconductor device.

To achieve the purpose described above, one embodiment of the present disclosure provides a semiconductor device including a substrate, a shallow trench isolation and a plurality of bit line structures. The substrate includes a plurality of active areas. The shallow trench isolation is disposed in the substrate and includes a first insulating layer being higher than a top surface of the substrate, and a second insulating layer disposed on the first insulating layer and being lower than the top surface of the substrate. The plurality of bit line structures is disposed on the substrate, extending in a first direction and arranged in a second direction being perpendicular to the first direction. Each of the plurality of bit line structures at least includes a conductive layer disposed on the substrate, and at least one of the plurality of bit line structures intersects the plurality of active areas, and the first insulating layer and the second insulating layer of the shallow trench isolation. The at least one of the plurality of bit line structures includes a first insulating stacked structure, a second insulating stacked structure and a third insulating stacked structure respectively disposed on one of the plurality of active areas, the first insulating layer and the second insulating layer, and the first insulating stacked structure. The second insulating stacked structure and the third insulating stacked structure each includes a top surface being coplanar with each other, and different stacked materials from each other.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 5 are schematic diagrams illustrating a semiconductor device according to a first embodiment in the present disclosure, wherein:

FIG. 1 shows a schematic top view of a semiconductor device;

FIG. 2 shows a schematic cross-sectional view taken along cross-lines A-A′ and B-B′ in FIG. 1;

FIG. 3 shows a schematic cross-sectional view taken along a cross-line C-C′ in FIG. 1;

FIG. 4 shows a schematic cross-sectional view taken along a cross-line D-D′ in FIG. 1; and

FIG. 5 shows a schematic cross-sectional view taken along a cross-line E-E′ in FIG. 1.

FIG. 6 to FIG. 9 are schematic diagrams illustrating a method of fabricating a semiconductor device according to a preferably embodiment in the present disclosure, wherein:

FIG. 6 shows a schematic cross-sectional view of a semiconductor device after forming a spacer layer;

FIG. 7 shows a schematic cross-sectional view of a semiconductor device after forming a first overlaying material layer;

FIG. 8 shows a schematic cross-sectional view of a semiconductor device after forming performing a first planarization process; and

FIG. 9 shows a schematic cross-sectional view of a semiconductor device after forming a second overlaying material layer.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

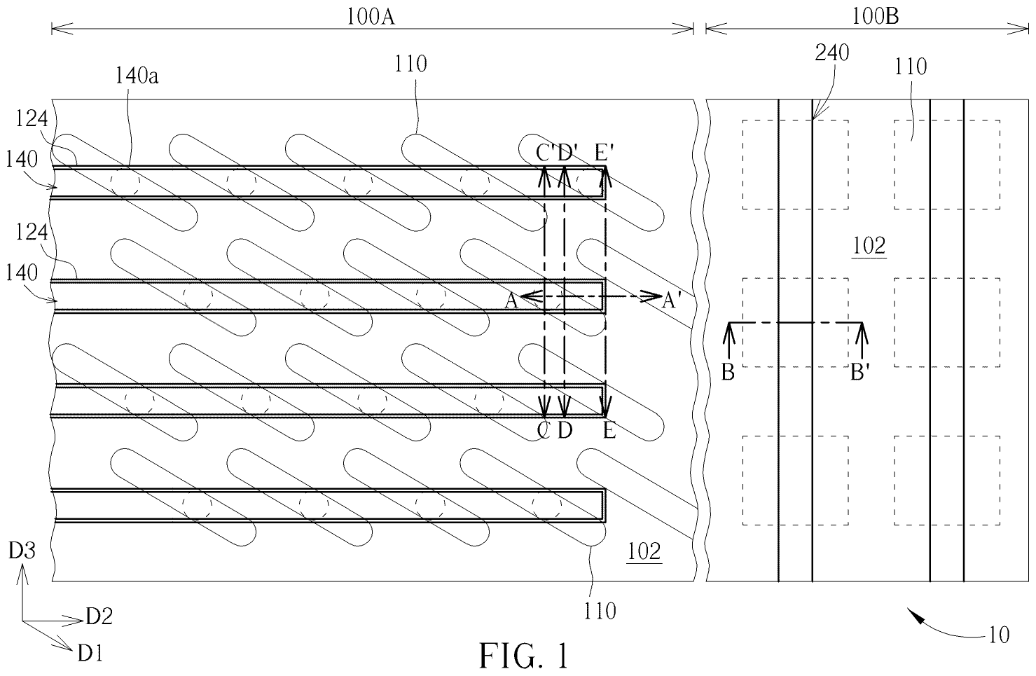

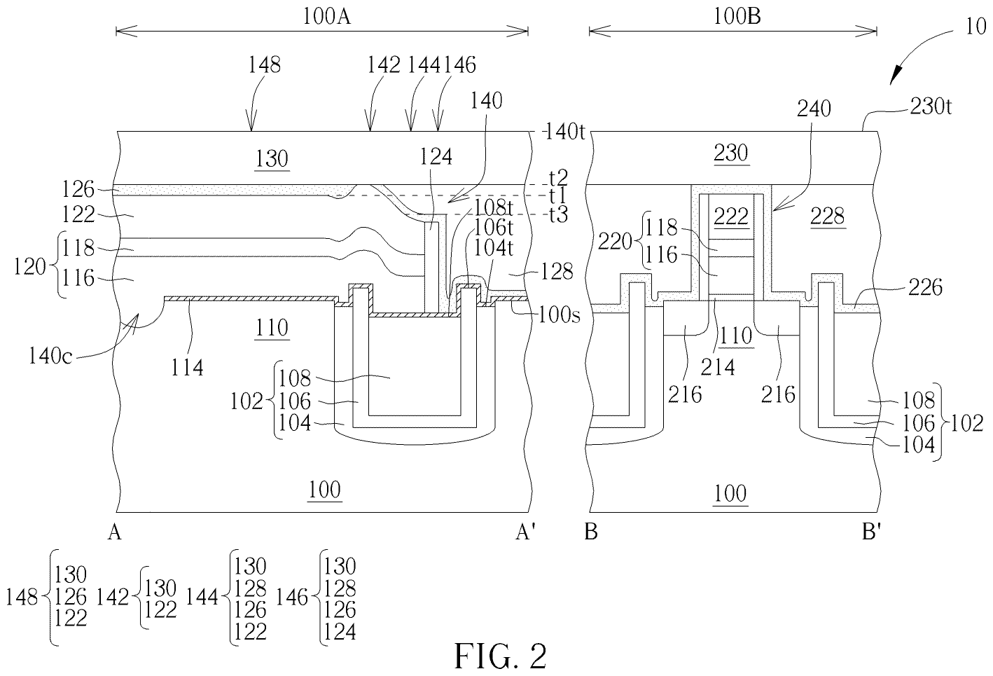

Please refer to FIG. 1 to FIG. 5, which are schematic diagrams illustrating a semiconductor device 10 according to a first embodiment of the present disclosure. Firstly, as shown in FIG. 1 and FIG. 2, the semiconductor device 10 includes a substrate 100, a shallow trench isolation 102, and a plurality of bit line structures 140. The substrate 100 for example includes a silicon substrate, a silicon-containing substrate (for example including SiC or SiGe) or a silicon-on-insulator (SOI) substrate, and the substrate 100 further includes a region with a relative higher elemental integration for example being a cell region 100A, and another region with a relative lower elemental integration for example being a peripheral region 100B, disposed thereon. The cell region 100A and the peripheral region 100B may be adjacent to each other, but not limited thereto. The shallow trench isolation 102 is disposed within the substrate 100, to define a plurality of active areas 110 respectively extending in a same direction D1. The shallow trench isolation 102 includes a multilayer structure, for example including a third insulating layer 104, a first insulating layer 106, and a second insulating layer 108 stacked in sequence, with a top surface 106t of the first insulating layer 106 being higher than a surface 100s of the substrate 100, a top surface 104t of the third insulating layer 104 and a top surface 108t of the second insulating layer 108, with the top surfaces 104t, 108t of the third insulating layer 104 and the second insulating layer 108 being lower than the surface 100s of the substrate 100, and with the top surface 104t of the third insulating layer 104 being higher than the top surface 108t of the second insulating layer 108, but not limited thereto. The bit line structures 140 are disposed on the substrate 100, and each of the bit line structures 140 further includes a conductive layer 120 and an insulating stacked structure stacked in sequence on the substrate 100, with the conductive layer 120 of each of the bit line structures 140 extending in a first direction D2 within the cell region 100A, to simultaneously intersect the active areas 110 and the shallow trench isolation 102 of the substrate 100. Accordingly, people skilled in the art should easily realize that each of the bit line structures 140 is exemplified as a strip-shaped structure extending in the first direction D2 and arranging in a second direction D3, as shown in FIG. 1 of the present embodiment, and the insulating stacked layers such as a second cover layer 130 and a second overlaying layer 230 disposed thereon have been omitted from FIG. 1, for clearly illustrating the strip-shaped structure of the bit line structures 140.

It is noted that, further in view of FIG. 1 and FIG. 2, each of the bit line structures 140 intersects the active areas 110 and the shallow trench isolation 102 within the substrate 100 at the same time, such that, the conductive layer 120 and the insulating stacked layers disposed thereon will conformally overlay the active areas 110, and the third insulating layer 104, the first insulating layer 106, and the second insulating layer 108 of the shallow trench isolation 102. Accordingly, various portions of each of the bit line structures 140 may include different insulating stacked structures 148, 142, 144 over the active areas 110, the first insulating layer 106 and the second insulating layer 108 of the shallow trench isolation 102, respectively. Precisely, one of the bit line structures 140 includes a first insulating stacked structure 148 over the active areas 110, a second insulating stacked structure 142 over the first insulating layer 106, and a third insulting stacked structure 144 over the second insulating layer 108. As shown in FIG. 2, top surfaces of the first insulating stacked structure 148, the second insulting stacked structure 142, and the third insulating stacked structure 144 are coplanar and located at a same plane 140t, and each of the first insulating stacked structure 148, the second insulting stacked structure 142, and the third insulating stacked structure 144 includes stacked layers in different number and materials. Through these arrangements, different insulating stacked structures such as the first insulating stacked structure 148, the second insulting stacked structure 142, and the third insulating stacked structure 144 are disposed on the conductive layer 120, and the bit line structures 140 are capable of achieving various insulating performances in different extending regions corresponding thereto. In this way, the semiconductor device 10 of the present disclosure will therefore gain the better component structure and functions, to improve the operation of the semiconductor device 10.

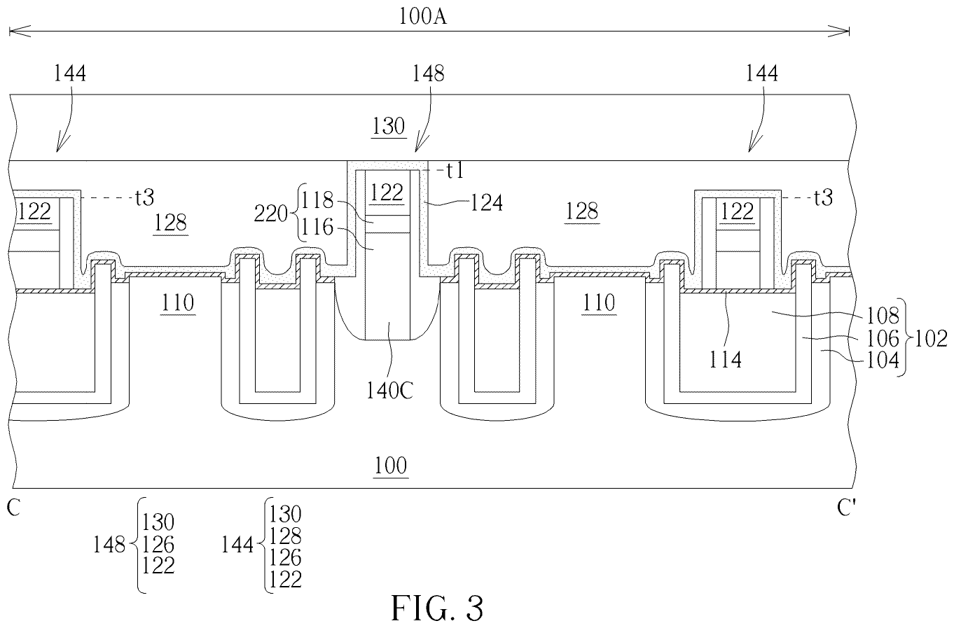

As shown in FIG. 2 and FIG. 3, the conductive layer 120 for example includes a semiconductor layer 116 (for example including a semiconductor material such as doped polysilicon and doped amorphous silicon), a barrier layer (not shown in the drawings, for example including a conductive barrier material such as titanium and/or titanium nitride, tantalum and/or tantalum oxide), and a metal layer 118 (for example including copper, aluminum, tungsten or any other suitable low-resistivity conductive material) stacked in sequence from bottom to top on the substrate 100. Generally, the bit line structures 140 are separately disposed on an dielectric layer 114 (for example including an oxide-nitride-oxide structure stacked in sequence) over the substrate 100, with a portion of the semiconductor layer 116 further extending into the substrate 100 to serve as bit line contacts (BLCs) 140c, such that each of the bit line structures 140 is allowable to be electrically connected to the corresponding active areas 112 via the monolithic bit line contacts 140c disposed underneath.

Precisely speaking, the first insulating stacked structure 148 disposed over one corresponding active area 110 includes a first cover layer 122, a barrier layer 126 and a second cover layer 130 stacked in sequence on the conductive layer 120, with the first cover layer 122, the barrier layer 126, and the second cover layer 130 in physical contact with each other. In one embodiment, the first cover layer 122, the barrier layer 126, and the second cover layer 130 for example respectively include an insulating material like silicon nitride, silicon carbonitride, silicon oxynitride, or a combination thereof, and the first cover layer 122, the barrier layer 126, and the second cover layer 130 preferably each includes a different material, but not limited thereto. On the other hand, the third insulating structure 144 disposed over the second insulating layer 108 includes the first cover layer 122, the barrier layer 126, an oxide layer 128, and the second cover layer 130 stacked in sequence on the conductive layer 120. That is, the oxide layer 128 is additionally disposed between the barrier layer 126 and the second cover layer 130 of the third insulating stacked structure 144, and which may include an insulating material like silicon oxide, to physically contact the second cover layer 130 disposed above and the barrier layer 126 disposed underneath.

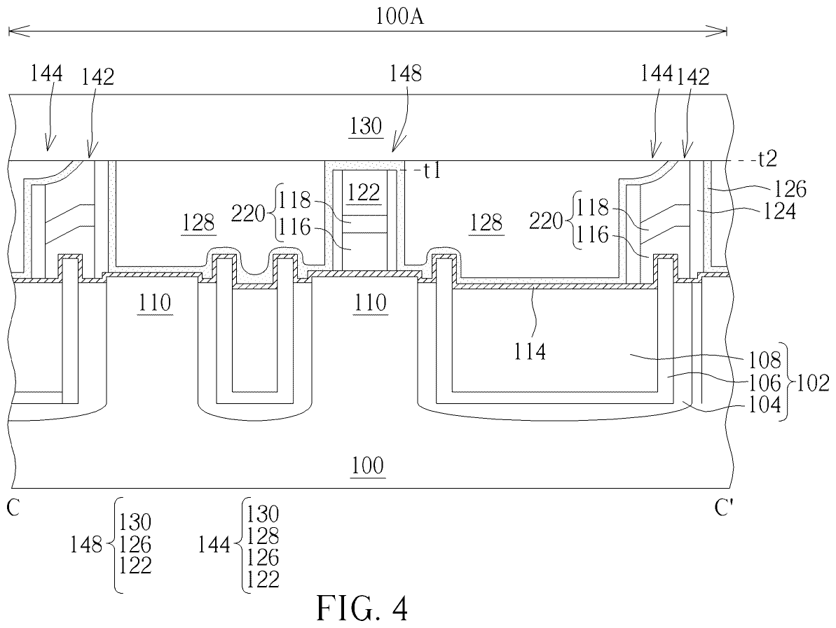

As shown in FIG. 2 and FIG. 4, the second insulating stacked structure 142 for example includes the first cover layer 122 and the second cover layer 130 stacked in sequence on the conductive layer 120. That is, the first cover layer 122 and the second cover layer 130 within the second insulating stacked structure 142 are in direct contact with each other, without any barrier layer disposed therebetween. A topmost surface t1 of the first cover layer 122 within the first insulating stacked structure 148 is higher than a topmost surface t3 of the first cover layer 122 within the third insulating stacked structure 144, and is lower than a topmost surface t2 of the first cover layer 122 within the second insulating stacked structure 142, but not limited thereto.

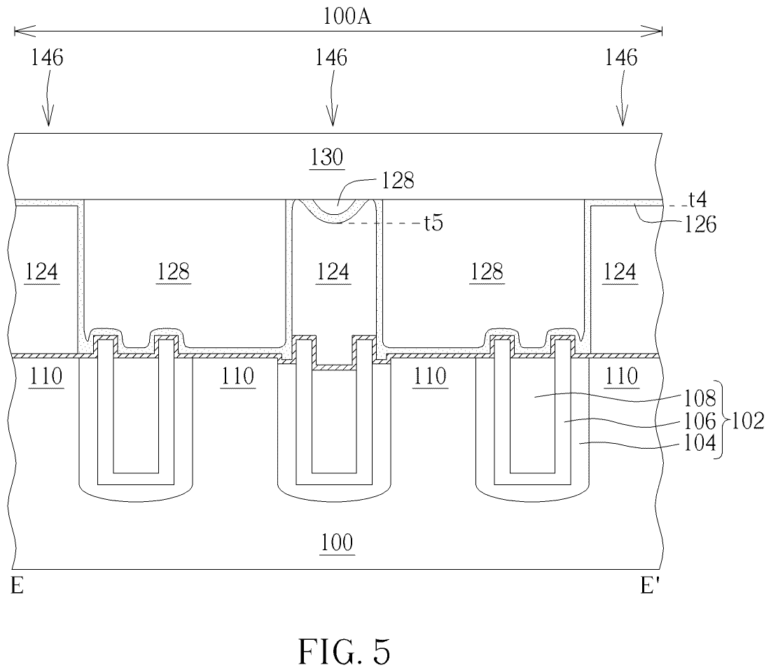

As shown in FIG. 2 and FIG. 5, each of the bit line structures 140 further includes a fourth insulating stacked structure 146 at the end thereof. According to the extension area of each bit line structure 140, the fourth insulating stacked structure 146 may be optionally disposed over one corresponding active area 110 and/or the shallow trench isolation 102, to include different stacked layers. Also, a top surface of the fourth insulating stacked structure 146 is coplanar with the top surfaces of the first insulating stacked structure 148, the second insulating stacked structure 142, and the third insulating stacked structure 146, at the same plane 140t. Precisely speaking, while the end of one bit line structure 140 is disposed across a corresponding active area 110, the fourth insulating stacked structure 146 may include a spacer layer 124, the barrier layer 126 and the second cover layer 130 stacked in sequence on the conductive layer 120, with the spacer layer 124 having a relative higher top surface t4. On the other hand, while the end of another bit line structure 140 is disposed across the shallow trench isolation 102, the fourth insulating stacked structure 146 may include the spacer layer 124, the barrier layer 126, the oxide layer 128 and the second cover layer 130 stacked in sequence on the conductive layer 120, with the spacer layer 124 having a dishing surface t5 in a relative lower height, but not limited thereto. In one embodiment, the spacer layer 124 for example includes an insulating material like silicon oxide, silicon oxynitride, silicon nitride, or silicon carbonitride, and preferably includes an insulating material being different from that of the barrier layer 126, but not limited thereto. In another embodiment, the spacer layer 124 may optionally include a multilayer structure, for example including a nitride layer, an oxide layer and another nitride layer stacked in sequence on a sidewall of each bit line structure 140, but not limited thereto.

Further in view of FIG. 1 and FIG. 2, the semiconductor device 10 further includes a plurality of gate structures 240 disposed on the substrate 100. Precisely, the gate structures 240 for example extend in the second direction D3 within the peripheral region 100B, to intersect the active areas 110 and the shallow trench isolation 102 of the substrate 100 at the same time, and the gate structures 240 are sequentially arranged in the first direction D2. Each of the gate structures 240 further includes a gate dielectric layer 214, a conductive layer 220, a covering layer 222, and a spacer layer 224 disposed on the sidewall of the gate dielectric layer 214, the conductive layer 220 and the covering layer 222. The conductive layer 220 of the gate structures 240 also includes the semiconductor layer 116 (for example including a semiconductor material such as doped polysilicon and doped amorphous silicon), the barrier layer (not shown in the drawings, for example including a conductive barrier material such as titanium and/or titanium nitride, tantalum and/or tantalum oxide), and the metal layer 118 (for example including copper, aluminum, tungsten or any other suitable low-resistivity conductive material) stacked in sequence from bottom to top. In a preferably embodiment, the conductive layer 220 of the gate structures 240 for example includes the same material with that of the conductive layer 120 of the bit line structures 140, the covering layer 222 of the gate structures 240 for example includes the same material with that of the first cover layer 122 of the bit line structures 140, and the spacer layer 224 of the gate structures 240 for example includes the same material with that of the spacer layer 124 of the bit line structures 140, but not limited thereto.

Furthermore, a first overlaying layer 226, a second overlaying layer 228, and a third overlaying layer 230 are sequentially disposed on the gate structures 240, with the first overlaying layer 226 conformally covering on the spacer layer 224, the gate structures 240 and the substrate 100, with the second overlaying layer 228 covering on the first overlaying layer 226 to level with the first overlaying layer 226 disposed right above the gate structures 240, and with the third overlaying layer 230 covering on the second overlaying layer 228 and the first overlaying layer 226, to obtain a flat top surface 230t. The flat top surface 230t of the third overlaying layer 230 within the peripheral region 100B is preferably coplanar with the top surfaces (namely the plane 140t) of the first insulating stacked structure 148, the second insulating stacked structure 142, the third insulating stacked structure 144 and the fourth insulating stacked structure 146, but not limited thereto. In one embodiment, the first overlaying layer 226, the second overlaying layer 228 and the third overlaying layer 230 for example all include different insulating materials like silicon oxide, silicon nitride, silicon oxynitride or silicon carbonitride, respectively. The first overlaying layer 226 within the peripheral region 100B for example includes the same material with that of the barrier layer 126 within the cell region 100A, the second overlaying layer 228 within the peripheral region 100B for example includes the same material with that of the oxide layer 128 within the cell region 100A, and the third overlaying layer 230 within the peripheral region 100B for example includes the same material with that of the second cover layer 130 within the cell region 100A, but not limited thereto.

Through these arrangements, the gate structures 240 within the peripheral region 100B, and doped regions 216 disposed at two sides thereof in the substrate 100 will together configure as a transistor component, and the bit line structures 140, another transistor component, a capacitor and word line structures all within the cell region 100A will together configure as a dynamic random access memory (DRAM) device, with the bit line structures 140 and the word line structure receiving the required voltage signals from the substrate 100. Also, since each bit line structure 140 includes different insulating stacked structures in different extending regions, the bit line structure 140 is allowable to achieve various insulating performances among the different extending regions corresponding thereto, thereby improving the function and the operation of the semiconductor device.

According to the semiconductor device of the present embodiment, the insulating stacked structures with different stacked films and different materials and the coplanar top surface are respectively arranged on the conductive layer of the bit line structures, so that, each bit line structure is capable of obtain different insulating stacked structures within different regions, for achieving various insulating performances in different extending regions corresponding thereto. In this way, the semiconductor device of the present embodiment will therefore gain the better component structure and functions, to improve the operation of the semiconductor device.

In order to make people skilled in the art of the present disclosure easily understand the semiconductor device 10 of the present disclosure, the fabricating method of the semiconductor device 10 in the present disclosure will be further described below.

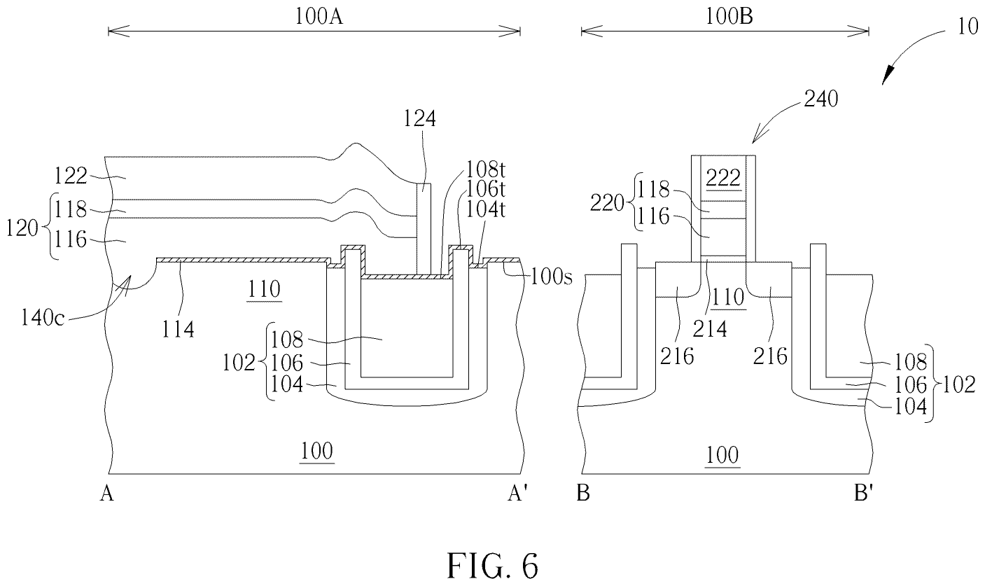

Please refer to FIG. 6 to FIG. 9, illustrating schematic diagrams of a fabricating method of the semiconductor device 10 according to the preferably embodiment in the present disclosure. Firstly, as shown in FIG. 6, a substrate 100 is provided, and the shallow trench isolation 102 is formed in the substrate 100, within the cell region 100A and the peripheral region 100B, to define the active areas 110 also in the substrate 100. In one embodiment, the formation of the shallow trench isolation 102 is for example carried out by firstly forming a plurality of trenches (not shown in the drawings) in the substrate 100 through an etching process, and sequentially forming the third insulating layer 104, the first insulating layer 106 and the second insulating layer 108 in each of the trenches, with the top surface 106t of the first insulating layer 106 being higher than the surface 100s of the substrate 100 and the top surfaces 104t, 108t of the third insulating layer 104 and the second insulating layer 108, with the top surfaces 104t, 108t of the third insulating layer 104 and the second insulating layer 108 being lower than the surface 100s of the substrate 100, and with the top surface 104t of the third insulating layer 104 being higher than the top surface 108t of the second insulating layer 108, but not limited thereto.

Next, the dielectric layer 114 is formed on the substrate 100, overlaying the active areas 110, and the third insulating layer 104, the first insulating layer 106 and the second insulating layer 108 in a conformal manner. Then, after removing the dielectric layer 114 within the peripheral region 100B, the conductive layer 120 and the first cover layer 122 of the bit line structures 140 are formed within the cell region 100A, and the gate structures 240 are formed within the peripheral region 100B. In one embodiment, the fabrication of the gate structures 240 may be integrated into the forming process of the conductive layer 120 and the first cover layer 122, and which may include but not limited to the following step. Firstly, a plurality of openings (not shown in the drawings) is formed through a mask (not shown in the drawings), penetrating through the dielectric layer 114 within the cell region 100A, and a chemical vapor deposition process is performed both within the cell region 100A and the peripheral region 100B, to form a semiconductor material layer (not shown in the drawings, for example including a semiconductor material such as doped polysilicon, doped phosphorus or silicon phosphorus) filling in the openings and further covering on the substrate 100. Then, a barrier material layer (not shown in the drawings, for example including a conductive barrier material such as titanium and/or titanium nitride, tantalum and/or tantalum oxide), a metal material layer (not shown in the drawings, for example including copper, aluminum, tungsten or any other suitable low-resistivity conductive material), and a first overlaying material layer (not shown in the drawings, for example including an insulating material like silicon nitride, silicon carbonitride or silicon oxynitride). It is noted that, since the top surfaces of the third insulating layer 104, the first insulating layer 106 and the second insulating layer 108 of the shallow trench isolation 102 are all in different heights, the first overlaying material layer, the metal material layer, the barrier material layer, the semiconductor material layer and the dielectric layer 114 formed thereon will therefore obtain the contour with various heights correspondingly, as shown in FIG. 6.

After that, at least one photolithography process is performed, to pattern the first overlaying material layer and the conductive material layer (including the metal material layer, the barrier material layer and the semiconductor material layer) disposed underneath, to form the conductive layer 120 extending in the first direction D2 within the cell region 100A, and the first cover layer over the conductive layer 120, and also to form the gate structures 240 extending in the second direction D3 within the peripheral region 100B. accordingly, the conductive layer 220 of the gate structures 240 may preferably include the same material with that of the conductive layer 120 of the bit line structures 140, and the covering layer 222 of the gate structures 240 may preferably include the same material with that of the first cover layer 122 of the bit line structures 140, but not limited thereto. Then, through the similar fabricating processes, the spacer layer 124 is formed on the sidewall of the conductive layer 120 and the first cover layer 122 of each bit line structure 140, and the spacer layer 224 is simultaneously formed on the sidewall of the conductive layer 220 and the covering layer 222 of each gate structure 240. In one embodiment, the fabrication of the spacer layer 224 may also be integrated into the forming process of the spacer layer 124 within the cell region 100A, so that, the spacer layer 224 within the peripheral region 100B and the spacer layer 124 within the cell region 100A will include the same material, but not limited thereto.

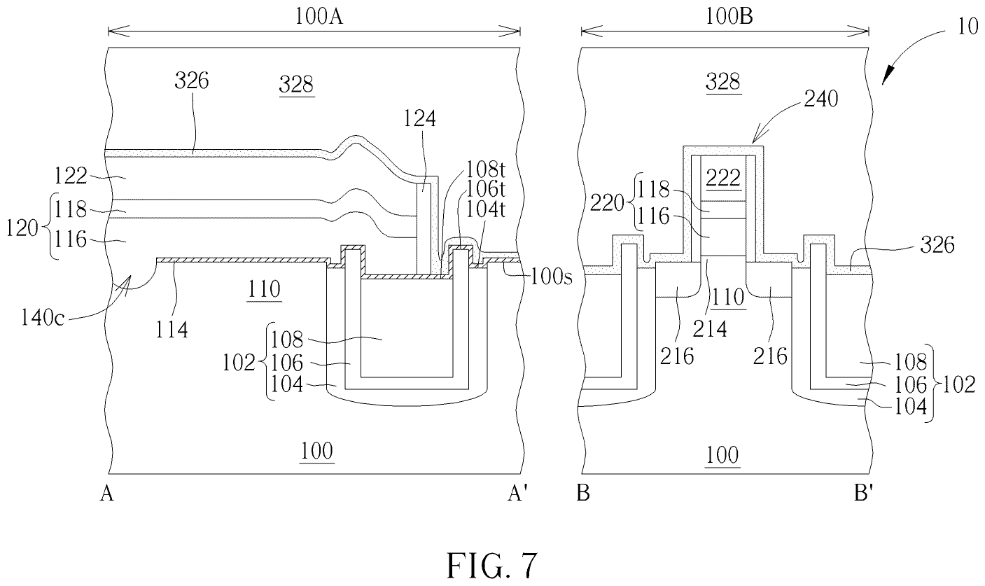

As shown in FIG. 7, another chemical vapor deposition process is performed both within the cell region 100A and the peripheral region 100B, to sequentially form a barrier material layer 326 and an oxide material layer 328. The barrier material layer 326 overlays the substrate 100, the conductive layer 120 and the first cover layer 122 of each bit line structures 140 within the cell region 100A, and each gate structure 240 within the peripheral region 100B in a conformal manner, thereby present in the contour with various heights. The oxide material layer 328 entirely covers the barrier material layer 326, to obtain a flat top surface. In one embodiment, the barrier material layer 326 for example includes an insulating material like silicon oxide, silicon nitride, silicon carbonitride or silicon oxynitride, and preferably includes an insulating material being different from that of the spacer layer 124 or the spacer layer 224, and the oxide material layer 328 for example includes an insulating material like silicon oxide ore silicon oxynitride, but not limited thereto.

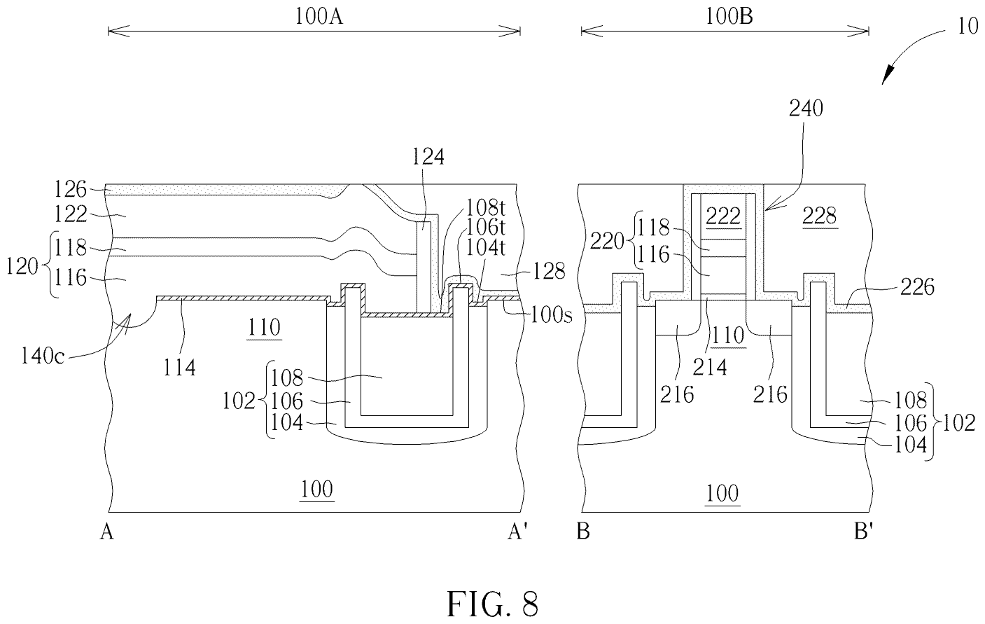

As shown in FIG. 8, a first planarization process is performed, to partially remove the oxide material layer 328, and to simultaneously form the oxide layer 128 within the cell region 100A and the second overlaying layer 228 within the peripheral region 100B. It is noted that, while performing the first planarization process, the barrier material layer 328 right over the gate structures 240 within the peripheral region 100B is used as a stop layer. Also, due to the contour in different heights of the barrier material layer 328 within the cell region 100A, the barrier material layer 328 and the first cover layer 122 disposed underneath are both partially removed while performing the first planarization process, thereby simultaneously forming the barrier layer 126 within the cell region 100A, and the first overlaying layer 226 within the peripheral region 100B. That is, after the first planarization process is performed, the barrier material layer 326 covering the first insulating layer 106 of the shallow trench isolation 102, within the cell area 100A is removed, to expose the first cover layer 122 underneath.

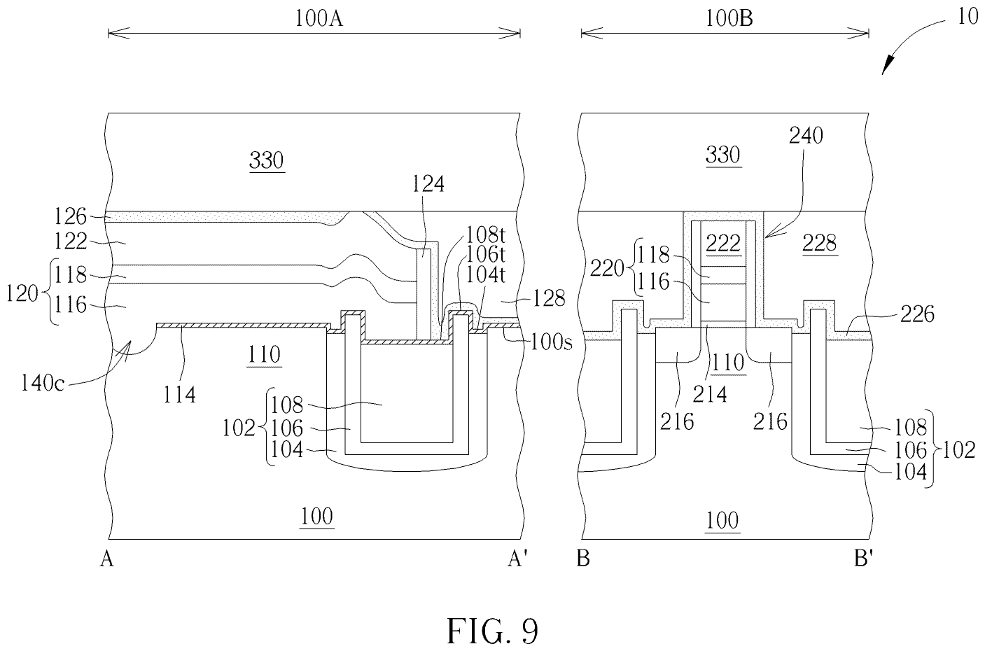

As shown in FIG. 9, another chemical vapor deposition process is performed both within the cell region 100A and the peripheral region 100B, to form a second overlaying material layer 330 entirely covering the barrier layer 126 and the oxide layer 128 within the cell region 100A, and covering the second overlaying layer 228 within the peripheral region 100B. The second overlaying material layer 330 includes a flat top surface. In one embodiment, the second overlaying material layer 330 for example includes an insulating material like silicon nitride, silicon carbonitride, silicon oxynitride or a combination thereof, and preferably includes an insulating material being different from that of the oxide material layer 328, but not limited thereto. Then, a second planarization process is performed, to partially remove the second overlaying material layer 330 within the cell region 100A and within the peripheral region 100B, to form the second cover layer 130 as shown in FIG. 2 within the cell region 100A, and to form the third overlaying layer 230 as shown in FIG. 2 within the peripheral region 100B. Accordingly, the first cover layer 122, the barrier layer 126, and the second cover layer 130 stacked in sequence over the active area 110, within the cell region 100A together form the first insulating stacked structure 148 as shown in FIG. 2, the first cover layer 122 and the second cover layer 130 stacked in sequence over the first insulating layer 106 of the shallow trench isolation 102 together form the second insulating stacked structure 142 as shown in FIG. 2, the first cover layer 122, the barrier layer 126, the oxide layer 128 and the second cover layer 130 stacked in sequence over the second insulating layer 108 of the shallow trench isolation 102 together form the third insulating stacked structure 144 as shown in FIG. 2. Also, the spacer layer 124, the barrier layer 126, the oxide layer 128 and the second cover layer 130 also stacked in sequence over the second insulating layer 108 of the shallow trench isolation 102 together form the fourth insulating stacked structure 146, located at the end of each bit line structure 140. Through these performances, the fabrication of the semiconductor device 10 of the present embodiment is accomplished, in which the insulating stacked structures with different materials and the coplanar top surface are formed over the conductive layer 120 of each bit line structure 140, under a simplified process flow, so as to achieve various insulating performances in different extending regions corresponding thereto.

According to the fabricating method of the present embodiment, the shallow trench isolation with top surfaces in different heights are formed before forming the conductive layer of the bit line structures, so that, the conductive layer formed subsequently over the active areas and the shallow trench isolation will therefore obtain the corresponding contour with different heights. In this way, the insulating stacked structures each having a coplanar top surface and different stacked materials are then formed on the conductive layer of a bit line structure, so that, the bit line structure enables to achieve various insulating performances in different extending regions corresponding thereto, thereby improving the function and the operation of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, comprising a plurality of active areas;
a shallow trench isolation, disposed in the substrate and comprising a first insulating layer being higher than a top surface of the substrate, and a second insulating layer disposed on the first insulating layer and being lower than the top surface of the substrate; and
a plurality of bit line structures, disposed on the substrate, the plurality of bit line structures extending in a first direction and arranged in a second direction being perpendicular to the first direction, each of the plurality of bit line structures at least comprises a conductive layer disposed on the substrate;
wherein at least one of the plurality of bit line structures intersects the plurality of active areas, and the first insulating layer and the second insulating layer of the shallow trench isolation, the at least one of the plurality of bit line structures comprises a first insulating stacked structure, a second insulating stacked structure and a third insulating stacked structure respectively disposed on one of the plurality of active areas, the first insulating layer and the second insulating layer, and the first insulating stacked structure, the second insulating stacked structure and the third insulating stacked structure each comprises a top surface being coplanar with each other and different stacked materials from each other.

2. The semiconductor device according to claim 1, wherein the second insulating stacked structure comprises a first cover layer and a second cover layer stacked in sequence from bottom to top on the conductive layer and in direct contact with each other, and the third insulating stacked structure comprises the first cover layer, a barrier layer, an oxide layer, and the second cover layer stacked in sequence from bottom to top on the conductive layer and in direct contact with each other.

3. The semiconductor device according to claim 2, wherein a topmost surface of the first cover layer of the second insulating stacked structure is higher than a topmost surface of the first cover layer of the third insulating stacked structure.

4. The semiconductor device according to claim 2, wherein the first insulating stacked structure comprises the first cover layer, the barrier layer and the second cover layer stacked in sequence from bottom to top on the conductive layer and in direct contact with each other.

5. The semiconductor device according to claim 4, wherein a topmost surface of the first cover layer of the first insulating stacked structure is higher than a topmost surface of the first cover layer of the third insulating stacked structure, and is lower than a topmost surface of the first cover layer of the second insulating stacked structure.

6. The semiconductor device according to claim 2, wherein the shallow trench isolation further comprises a third insulating layer, and the first insulating layer is disposed on the third insulating layer, wherein a top surface of the third insulating layer is lower than the top surface of the substrate and a top surface of the first insulating layer, and the top surface of the third insulating layer is higher than a top surface of the second insulating layer.

7. The semiconductor device according to claim 6, wherein the at least one of the plurality of bit line structures further comprises a fourth insulating stacked structure disposed on the second insulating layer, and the fourth insulating stacked structure comprises a spacer layer, the barrier layer, the oxide layer, and the second cover layer.

8. The semiconductor device according to claim 7, wherein a top surface of the fourth insulating stacked structure is coplanar with the top surface of the first insulating stacked structure, the top surface of the second insulating stacked structure, and the top surface of the third insulating stacked structure.

9. The semiconductor device according to claim 7, further comprising:
at least one gate structure, disposed on the substrate and at least comprising another conductive layer and another spacer layer, wherein the another conductive layer of the at least one gate structure and the conductive layer of the at least one of the plurality of bit line structures comprise a same conductive material;
a first overlaying layer, disposed on the at least one gate structure;
a second overlaying layer, disposed on the first overlaying layer; and
a third overlaying layer, disposed on the second overlaying layer.

10. The semiconductor device according to claim 9, wherein a material of the first overlaying layer is the same as a material of the barrier layer, a material of the second overlaying layer is the same as the oxide layer, and a material of the third overlaying layer is the same as a material of the second cover layer.
